(19) United States
(12) Patent Application Publication
(10) Pub. No.: US 2026/0150679 A1
(43) Pub. Date: May 28, 2026

(54) ENHANCED COOLING OF A HIGH-POWER RADIO FREQUENCY FLIP-CHIP DIE USING A THERMAL-SPREADING INTERPOSER

(71) Applicant: Qorvo US, Inc., Greensboro, NC (US)

(72) Inventors: MD Hasnine, Wylie, TX (US); Charles Edward Carpenter, Orlando, FL (US)

(21) Appl. No.: 19/353,026

(22) Filed: Oct. 8, 2025

Related U.S. Application Data
(60) Provisional application No. 63/725,676, filed on Nov. 27, 2024.

(51) Int. Cl. H01L 23/373; H01L 21/48; H01L 23/00; H01L 23/31; H01L 23/367; H01L 23/498; H01L 23/552

(52) U.S. Cl. CPC H10W 40/259; H10W 40/22; H10W 42/20; H10W 70/093; H10W 70/095; H10W 70/635; H10W 74/117; H10W 74/121; H10W 90/401; H10W 90/701; H10W 99/00; H10W 74/142; H10W 74/15; H10W 76/12; H10W 76/17; H10W 90/724; H10W 90/734

(57) ABSTRACT

Aspects of the disclosure provide a semiconductor package and a method of producing the same. The disclosed semiconductor package includes a substrate; an interposer attached to the substrate, the interposer comprising one or more through vias across the interposer; a flip-chip (FC) die attached to the interposer via a plurality of copper posts; and a silicon carbide (SiC) heat spreader disposed on atop the FC die via a layer of sinter material. In various embodiments, a wireless device may include the disclosed semiconductor package. In one or more embodiments, a wireless device may include the semiconductor package produced via the method as disclosed herein.

### CROSS-REFERENCE TO RELATED APPLICATION

This application claims priority to U.S. Patent Application No. 63/725,676, filed Nov. 27, 2024, all of which is incorporated by reference herein in its entirety.

### TECHNICAL FIELD

The present disclosure relates generally to semiconductor cooling methodologies, and in particular, relates to a semiconductor package and a method for making a semiconductor package with advanced cooling solutions.

### BACKGROUND

Advanced semiconductor electronics are typically assembled using cutting-edge packaging techniques. As known in the industry, semiconductor packaging using 3D (three-dimensional) stacking can offer seamless integration of various sensitive components in a compact space. While rapid advances in 3D packaging processes necessitate the development of intricate systems in electronic designs within a smaller footprint, they can nevertheless lead to more pronounced thermal issues from resulting high temperatures due to the enormous heat generated by the densely stacked dies. This is particularly apparent when gate spacing is reduced in devices, such as, for example, high-power radio frequency (RF) gallium nitride (GaN)/gallium arsenide (GaAs) devices, which often result in intensified heat concentration that causes device heating and elevated junction temperatures. This uncontrolled elevation may detrimentally affect both performance and reliability such high-power devices. Indeed, the heat generated from these devices is quite intense that conventional heat sinks prove to be insufficient in dispersing such concentrated heat flux.

Current high-power flip-chip GaN dies, for example, primarily dissipate heat from the backside of the dies, with minimal heat transfer through the laminate. This approach is often inefficient due to the laminate's high thermal resistance and such inefficiency can negatively impact performance and reliability. With on-going adaptation of heterogeneous integration and miniaturization, thermal challenges intensify as densely packed or side-by-side assembled multiple dies generate significant heat, leading to elevated temperatures. Therefore, advanced packaging solutions are essential for enhanced cooling of wide bandgap semiconductors, such as, GaN, GaAs, and silicon carbide (SiC). Consequently, there is a demand for advanced thermal solutions tailored for support package miniaturization while integrating air cavity options to enhance RF performance and overmolded options to improve package robustness for wide bandgap semiconductors.

### SUMMARY

Embodiments of the present disclosure include advanced semiconductor packaging techniques with innovative cooling capabilities designed for wide band gap semiconductor packages. Aspects of the disclosure advantageously provide a semiconductor package and one or more methods of making a semiconductor package with advanced cooling solutions.

In an exemplary aspect, a semiconductor package is provided. The semiconductor package includes a substrate; an interposer attached to the substrate, the interposer comprising one or more through vias across the interposer; a flip-chip (FC) die attached to the interposer via a plurality of copper posts; and a silicon carbide (SiC) heat spreader disposed on atop the FC die via a layer of sinter material.

In one or more embodiments, the one or more through vias of the interposer comprises copper and are configured to enable thermal conduction through and across the interposer. In one or more embodiments, the interposer has a larger lateral surface area than a lateral surface area of the FC die. In one or more embodiments, the interposer comprises a silicon carbide (SiC) thermal spreader and the one or more through vias comprises one or more through-silicon carbide vias.

In one or more embodiments, the SiC heat spreader is a first SiC heat spreader and the layer of sinter material is a first layer of sinter material, the semiconductor package may further include a second SiC heat spreader disposed atop the first SiC heat spreader via a second layer of sinter material. In one or more embodiments, the second SiC heat spreader is larger than the first SiC heat spreader and comprises extensions that are in thermal contact with the substrate via a third layer of sinter material.

In one or more embodiments, the semiconductor package may further include a mold compound surrounding the FC die and the interposer. In one or more embodiments, the semiconductor package may further include a shielding encapsulating the mold compound. In one or more embodiments, the plurality of copper posts are in thermal contact with the one or more through vias. In one or more embodiments, a wireless device may include the semiconductor package as disclosed herein.

In an exemplary aspect, a method is provided. The method includes attaching an interposer to a substrate, the interposer comprising one or more through vias across the interposer; attaching a flip-chip (FC) die to the interposer via a plurality of copper posts; and disposing a silicon carbide (SiC) heat spreader atop the FC die via a layer of sinter material.

In one or more embodiments of the method, the one or more through vias of the interposer comprises copper and are configured to enable thermal conduction through and across the interposer. In one or more embodiments of the method, the interposer has a larger lateral surface area than a lateral surface area of the FC die. In one or more embodiments of the method, the interposer comprises a silicon carbide (SiC) thermal spreader and the one or more through vias comprises one or more through-silicon carbide vias.

In one or more embodiments, the SiC heat spreader is a first SiC heat spreader and the layer of sinter material is a first layer of sinter material, the method may further include attaching a second SiC heat spreader atop the first SiC heat spreader via a second layer of sinter material. In one or more embodiments, the second SiC heat spreader is larger than the first SiC heat spreader and comprises extensions that are in thermal contact with the substrate via a third layer of sinter material.

In one or more embodiments, the method may further include forming a mold compound to surround the FC die and the interposer. In one or more embodiments, the method may further include forming a shielding to encapsulate the mold compound. In one or more embodiments, the plurality of copper posts are in thermal contact with the one or more through vias. In one or more embodiments, a wireless device may include the semiconductor package produced via the method as disclosed herein.

In an exemplary aspect, a wireless device is provided. The wireless device may include a semiconductor package comprising a substrate, an interposer attached to the substrate, the interposer comprising one or more through vias across the interposer, a flip-chip die attached to the interposer via a plurality of copper posts, and a silicon carbide heat spreader disposed on atop the flip-chip die via a layer of sinter material.

Additional aspects, embodiments, implementations, features, and advantages of the present disclosure will become apparent from the following detailed description.

### BRIEF DESCRIPTION OF THE DRAWINGS

Illustrative embodiments of the present disclosure will be described with reference to the accompanying drawings, of which:

FIG. 1 illustrates a cross-sectional view of an example semiconductor package, according to aspects of the present disclosure.

FIG. 2 illustrates a cross-sectional view of an example semiconductor package, according to aspects of the present disclosure.

FIG. 3 illustrates a flowchart for a method for preparing an example semiconductor package, according to aspects of the present disclosure.

FIG. 4 illustrates an electronic device or a wireless device comprising a semiconductor package, according to aspects of the present disclosure.

### DETAILED DESCRIPTION

For the purposes of promoting an understanding of the principles of the present disclosure, reference will now be made to the embodiments illustrated in the drawings, and specific language will be used to describe the same. It is nevertheless understood that no limitation to the scope of the disclosure is intended. Any alterations and further modifications to the described devices, systems, and methods, and any further application of the principles of the present disclosure are fully contemplated and included within the present disclosure as would normally occur to one skilled in the art to which the disclosure relates. In particular, it is fully contemplated that the features, components, and/or steps described with respect to one embodiment may be combined with the features, components, and/or steps described with respect to other embodiments of the present disclosure. For the sake of brevity, however, the numerous iterations of these combinations will not be described separately.

In accordance with one or more embodiments herein, advanced thermal solutions tailored for wide bandgap semiconductors/modules and packaging that enable efficient cooling of such high-power modules thereof are disclosed. The disclosed semiconductor packaging/modules are designed and configured for materials, such as GaN, GaAs, and SiC, to facilitate their wide adoption and extensive utilization in high-power high-frequency applications.

This disclosed packaging and methodologies for forming such semiconductor packaging includes, for example, a SiC-based through-SiC via (TSiCV) thermal spreading interposer for a high-power RF flip-chip die, which provides both bottom-side heat spreading and cooling. Additionally, the disclosed packaging and methodologies allow integration of discrete heat spreaders alongside a continuous oversized cavity heat spreader for customer heat sink attachment and topside cooling. In one or more embodiments, the disclosed approach enables effective conduction of heat from the die to the top heat spreader, which is further supported by a continuous heat spreader. In accordance with one or more embodiments, a heat sink can also be added, as needed, to enable a further efficient topside cooling. As further discussed below, the SiC interposer with TSiCV attached via solder bumps facilitates bottom-side cooling by spreading heat from the active GaN flip-chip die to the large-area TSiCV thermal spreading interposer before dissipating it into the laminate. The disclosed thermal dissipation approach improves heat flow from the active GaN die to the high thermal conductive large-area SiC thermal spreader interposer, which helps prevent hot spot formations while enhancing overall efficiency in heat transfer within the semiconductor package. Furthermore, film-assisted molding or compression molding, and sputter shielding can be employed in the preparing of the disclosed semiconductor packages to ensure the robustness of the modules, its hermeticity, and its electromagnetic performance.

By implementing the disclosed packaging methodologies, efficient heat conduction from both sides of the die significantly reduces junction temperature. Enclosing the die within a cavity, for example, can enhance RF performance, while over molding the semiconductor package can improve robustness. Sputter shielding in such packages can further enhance electromagnetic performance. Therefore, with the disclosed packaging methodologies, heat can be efficiently removed from both sides of the die, which in turn helps improve the lifetime and RF performance of the semiconductor packages.

In accordance with one or more embodiments of the disclosure herein, the packaging method may include fabricating vias in the SiC thermal spreading interposer and filling them with a conductive material, such as but not limited to, copper. In one or more embodiments, the vias connect the top flip-chip (FC) die. In one or more embodiments, dielectric liners or passivation can be applied to the TSiCV pads, which is needed to prevent degradation of RF signals passing through the thermal interposer. After fabricating the TSiCV, the top surface of the SiC thermal spreader undergoes under bump metallization (UBM) via gold-nickel (Au/Ni) formation to enable the integration of high-power FC dies. The bottom side of the SiC thermal spreader then undergoes plated solder bump formation, allowing it to be attached to a laminate using solder flux and a standard surface mount technology (SMT) process. In doing so, the approach improves heat flow from the active GaN die to the highly thermally conductive large-area SiC thermal spreading interposer before dissipating into the laminate. This effectively enhances bottom-side heat transfer efficiency along with topside cooling, resulting in a reduction in junction temperature, as discussed herein.

In one or more embodiments disclosed herein, the packaging method may include attaching an interposer to a substrate, where the interposer includes one or more through vias across the interposer. The method may also include attaching a flip-chip (FC) die to the interposer via a plurality of copper posts and disposing a silicon carbide (SiC) heat spreader atop the FC die via a (first) layer of sinter material. In one or more embodiments of the disclosed packaging method, one or more through vias of the interposer may include copper and are configured to enable thermal conduction through and across the interposer. In one or more embodiments, the interposer has a larger lateral surface area than a lateral surface area of the FC die. In one or more embodiments of the method, the interposer may include a (first) SiC thermal spreader and in such instance, the vias are one or more through-silicon carbide vias (TSiCVs).

In one or more embodiments, the packaging method may further include attaching a second SiC heat spreader atop the first SiC heat spreader via a second layer of sinter material. In one or more embodiments, the second SiC heat spreader is larger than the first SiC heat spreader and may further include extensions (e.g., legs or posts) that are in thermal contact with the substrate via another (third) layer of sinter material. In one or more embodiments, the packaging method may further include forming a mold compound to surround the FC die and the interposer. In one or more embodiments, the packaging method may further include forming a shielding, such as for example, but not limited to stainless steel (SUS)-Cu-SUS, to encapsulate the mold compound to improve its hermeticity and the integrity of the SiC heat spreaders. In some embodiments, the copper posts may be in thermal contact with the through vias. In one or more embodiments, the packaging method may be configured to implement the disclosed package configuration to enhance RF performance by integrating high-density components in a small form factor.

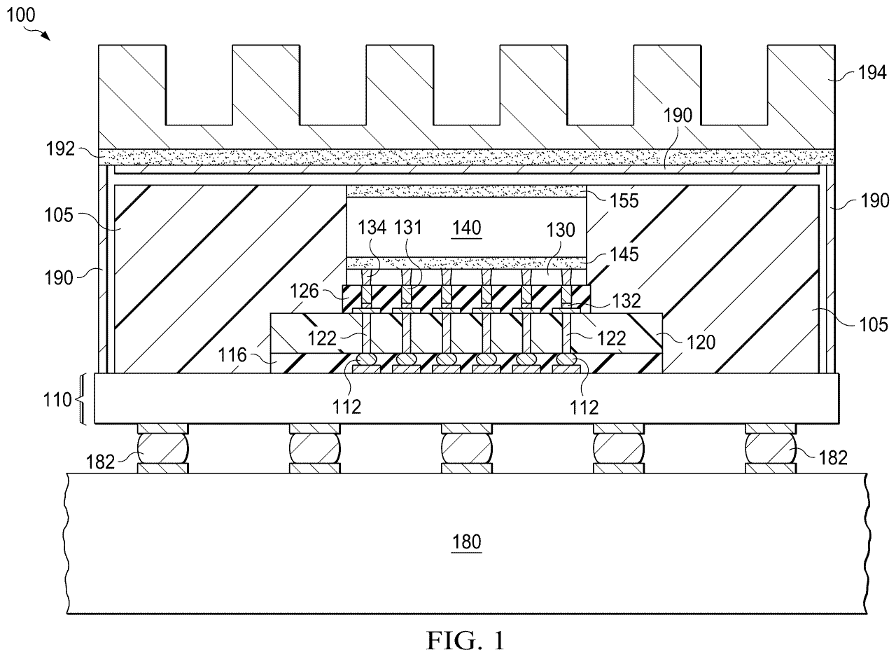

Various embodiments of the disclosed packaging and methodologies are described below in further detail with respect to the FIGS. 1, 2, 3, and 4.

FIG. 1 illustrates a cross-sectional view of an example semiconductor package 100, according to aspects of the present disclosure. In one or more embodiments, the semiconductor package 100 may include a wide band gap semiconductor package with advanced cooling solutions using a thermal spreading interposer. In some embodiments, the semiconductor package 100 may be produced or manufactured using advanced semiconductor packaging techniques as disclosed herein.

As illustrated in FIG. 1, the semiconductor package 100 includes a substrate 110, which may also be referred to herein as a laminate, in accordance with one embodiment. The semiconductor package 100 includes an interposer 120 attached to the substrate 110 via a set of solder bumps 112, as shown in FIG. 1. In one or more embodiments of the semiconductor package 100, the attachment of the interposer 120 may include, but not limited to, pick-and-place, flux printing or dipping, reflow, and cleaning steps, followed by underfill dispensing using an underfill 116 and curing thereafter.

In one or more embodiments, the interposer 120 may be a thermal spreading interposer and includes a plurality of vias 122 across the interposer 120, as shown in FIG. 1. In one or more embodiments, the vias 122 may include SiC-based through-SiC vias (TSiCVs), which may be filled with a conductive material, such as but not limited to, copper. In one or more embodiments, dielectric liners or passivation can be applied to pads of the TSiCVs, which may help prevent degradation of RF signals passing through the interposer 120.

As further illustrated in FIG. 1, the semiconductor package 100 includes a flip-chip (FC) die 130 attached to the interposer 120. In one or more embodiments, the vias 122 of the interposer 120 may be connected the FC die 130. In one or more embodiments, the FC die 130 may be attached to the substrate 110 via a plurality of copper posts or copper pillars 131 and solder caps 132 through via in die 134 within the FC die 130. Areas between the FC die 130 and the interposer 120 may be filled with underfill 126, as shown in FIG. 1.

In one or more embodiments, the semiconductor package 100 includes a silicon-carbide (SiC) heat spreader 140 disposed atop the FC die 130 via a layer of sinter material 145, as shown in FIG. 1. In one or more embodiments, the FC die 130 is in thermal contact with the SiC heat spreader 140 via the sinter material 145, wherein the sinter material 145 may include a coefficient of thermal expansion-matched material. In one or more embodiments, a CTE of the CTE-matched sinter material 145 matches a CTE of the SiC heat spreader 140 and/or a CTE of the FC die 130.

In one or more embodiments, the semiconductor package 100 may further include a mold compound 105 disposed adjacent to the SiC heat spreader 140, the FC die 130, and the interposer 120 such that the mold compound 105 forms a seal against moisture for the SiC heat spreader 140, the FC die 130, and the interposer 120, as shown in FIG. 1. In one or more embodiments, the mold compound 105 may form a near-hermitic seal for the SiC heat spreader 140, the FC die 130, and the interposer 120.

As further illustrated in FIG. 1, the semiconductor package 100 may further include a sputter-deposited coating or sputter shield 190 over the mold compound 105, in one or more embodiments. In one or more embodiments, the semiconductor package 100 may further include a heat sink 194 disposed on the sputter shield 190 and a thermal interface material (TIM) 192 disposed between the sputter shield 190 and the heat sink 194.

In one or more embodiments, the semiconductor package 100 may further include a printed circuit board (PCB) 180 attached to a second side or the bottom side of the substrate 110, as shown in FIG. 1. In one or more embodiments, the PCB 180 may be attached to the bottom side of the substrate 110 via solder 182, for example, in a ball grid array (BGA) or a land grid array (LGA).

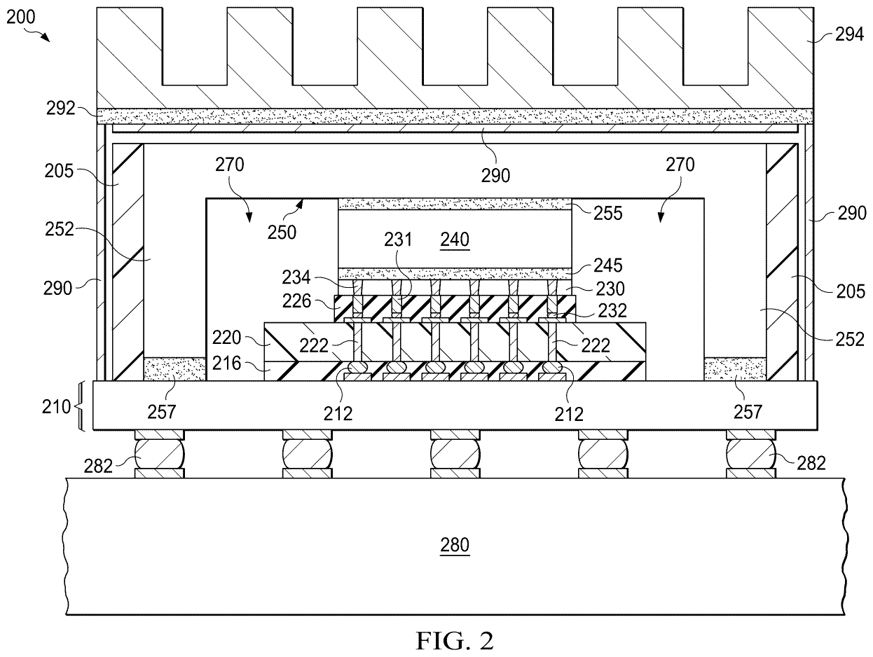

Now referring to FIG. 2, which illustrates a cross-sectional view of an example semiconductor package 200, according to aspects of the present disclosure. In one or more embodiments, the semiconductor package 200 may include a wide band gap semiconductor package using a thermal spreading interposer, as discussed here. In one or more embodiments, the semiconductor package 200 may be produced or manufactured using advanced semiconductor packaging techniques in accordance with various aspects of the present disclosure.

As illustrated in FIG. 2, the semiconductor package 200 includes a substrate 210 (also referred to herein as a laminate), in accordance with one embodiment. The semiconductor package 200 includes an interposer 220 attached to the substrate 210 via a set of solder bumps 212, as shown in FIG. 2. In one or more embodiments of the semiconductor package 200, similar to the semiconductor package 100, the attachment of the interposer 220 may include, but not limited to, pick-and-place, flux printing or dipping, reflow, and cleaning steps, followed by underfill dispensing using an underfill 216 and curing the underfill 216 thereafter.

In one or more embodiments, the interposer 220 may be a thermal spreading interposer and includes a plurality of vias 222 across the interposer 220, as shown in FIG. 2. In one or more embodiments, the vias 222 may include SiC-based through-SiC vias (TSiCVs), which may be filled with a conductive material, such as but not limited to, copper. In one or more embodiments, dielectric liners or passivation can be applied to pads of the TSiCVs, which may help prevent degradation of RF signals passing through the interposer 220.

As further illustrated in FIG. 2, the semiconductor package 200 includes a FC die 230 attached to the interposer 220. In one or more embodiments, the vias 222 of the interposer 220 may be connected the FC die 230. In one or more embodiments, the FC die 230 may be attached to the substrate 210 via a plurality of copper posts or copper pillars 231 and solder caps 232 through via in die 234 within the FC die 230. Areas between the FC die 230 and the interposer 220 may be filled with underfill 226, as shown in FIG. 2.

In one or more embodiments, the semiconductor package 200 includes a silicon-carbide (SiC) heat spreader 240 disposed atop the FC die 230 via a layer of sinter material 245, as shown in FIG. 2. In one or more embodiments, the FC die 230 is in thermal contact with the SiC heat spreader 240 via the sinter material 245, wherein the sinter material 245 may include a coefficient of thermal expansion-matched material. In one or more embodiments, a CTE of the CTE-matched sinter material 245 matches a CTE of the SiC heat spreader 240 and/or a CTE of the FC die 230.

As further illustrated in FIG. 2, the semiconductor package 200 includes an oversized SiC heat spreader 250 attached to the SiC heat spreader 240. In one or more embodiments, the oversized SiC heat spreader 250 is attached to the SiC heat spreader 240 via a second layer of sinter material 255. As further illustrated in FIG. 2, the oversized SiC heat spreader 250 includes one or more extensions or walls 252, for example, at edges along a boundary, and/or circumferentially of the oversized SiC heat spreader 250. The one or more extensions or walls 252 are in contact with the substrate 210 at a plurality of locations of the substrate 210 via a third layer of sinter material 257, as illustrated in the cross-sectional view of FIG. 2. In other words, the oversized SiC heat spreader 250 with its one or more extensions or walls 252 is connected to the substrate 210 via the sinter material 257 in such a way to create an air cavity 270, as shown in FIG. 2. In one or more embodiments, the oversized SiC heat spreader 250 is mounted in the semiconductor package 200 in a configuration such that the air cavity 270 surrounds the SiC heat spreader 240, the FC die 230, and the interposer 220, and seals against the substrate 210, as shown in FIG. 2.

In one or more embodiments, the semiconductor package 200 may further include a mold compound 205 around one or more sides (or circumferentially) of the oversized SiC heat spreader 250 such that the mold compound 205 forms a seal against moisture for the oversized SiC heat spreader 250, the SiC heat spreader 240, the FC die 230, and the interposer 220, as shown in FIG. 2. In one or more embodiments, the mold compound 205 may form a near-hermitic seal for the oversized SiC heat spreader 250, the SiC heat spreader 240, the FC die 230, and the interposer 220.

As further illustrated in FIG. 2, the semiconductor package 200 may further include a sputter-deposited coating or sputter shield 290 over the mold compound 205, in one or more embodiments. In one or more embodiments, the semiconductor package 200 may further include a heat sink 294 disposed on the sputter shield 290 and a thermal interface material (TIM) 292 disposed between the sputter shield 290 and the heat sink 294.

In one or more embodiments, the semiconductor package 200 may further include a printed circuit board (PCB) 280 attached to a second side or the bottom side of the substrate 210, as shown in FIG. 2. In one or more embodiments, the PCB 280 may be attached to the bottom side of the substrate 210 via solder 282, for example, in a ball grid array (BGA) or a land grid array (LGA).

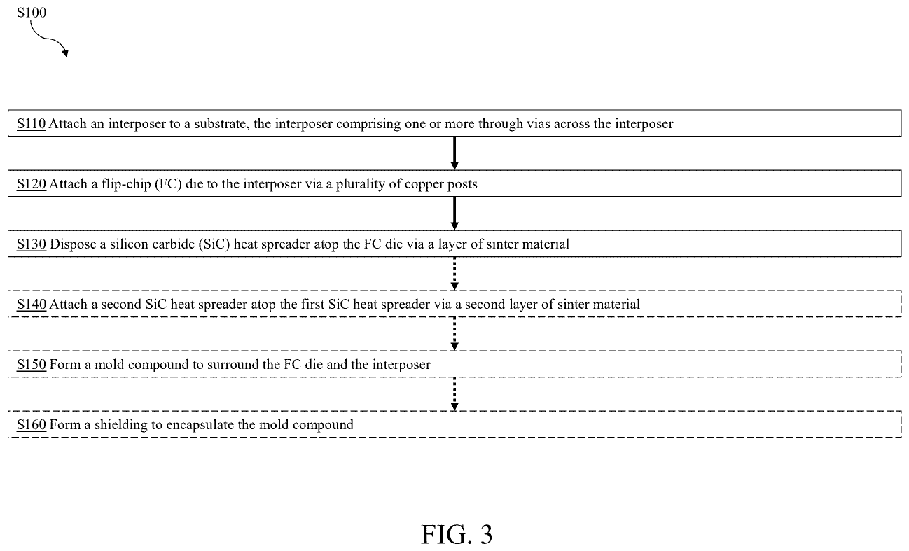

FIG. 3 illustrates a flowchart for a method S100 for preparing an example semiconductor package, according to aspects of the present disclosure. In one or more embodiments, the semiconductor package formed via the method S100 may include a semiconductor package, such as the semiconductor packages 100 and 200, as described with respect to FIGS. 1 and 2. As shown in FIG. 3, the method S100 includes, at step S110, attaching an interposer to a substrate, the interposer comprising one or more through vias across the interposer. In one or more embodiments, the substrate includes a substrate, such as the substrates 110 or 210, the interposer includes an interposer, such as the interposer 120 or 220, and the one or more through vias include one or more through vias, such as, the one or more through vias 122 or 222, as described with respect to FIGS. 1 and 2.

The method S100 further includes, at step S120, attaching a flip-chip (FC) die to the interposer via a plurality of copper posts. In one or more embodiments, the FC die includes a FC die, such as the FC die 130 or 230, the plurality of copper posts include copper posts, such as the copper posts 131 or 231, as described with respect to FIGS. 1 and 2. The method S100 further includes, at step S130, disposing a silicon carbide (SiC) heat spreader atop the FC die via a layer of sinter material. In one or more embodiments, the SiC heat spreader includes a SiC heat spreader, such as the SiC heat spreader 140 or 240, the layer of sinter material includes a sinter material, such as the sinter material 145 or 245, as described with respect to FIGS. 1 and 2.

In one or more embodiments of the method S100, the one or more through vias of the interposer may include copper and are configured to enable thermal conduction through and across the interposer. In one or more embodiments, the interposer may have a larger lateral surface area than a lateral surface area of the FC die. In one or more embodiments, the interposer may include a silicon carbide (SiC) thermal spreader. In one or more embodiments, the one or more through vias may include one or more through-silicon carbide vias, as disclosed herein.

In one or more embodiments, the SiC heat spreader is a first SiC heat spreader and the layer of sinter material is a first layer of sinter material, the method S100 may further include, optionally at step S140, attaching a second SiC heat spreader atop the first SiC heat spreader via a second layer of sinter material. In one or more embodiments, the second SiC heat spreader includes an oversized SiC heat spreader, such as the oversized SiC heat spreader 250, and the second layer of sinter material includes a sinter material, such as the sinter material 255, as described with respect to FIG. 2. In one or more embodiments, the second SiC heat spreader is larger than the first SiC heat spreader and includes extensions or walls, such as extensions or walls 252, that are in thermal contact with the substrate via a third layer of sinter material, such as sinter material 257, as described with respect to FIG. 2.

In one or more embodiments, the method S100 may further include, optionally at step S150, forming a mold compound to surround the FC die and the interposer. In one or more embodiments, the mold compound includes a mold compound, such as the mold compound 105 or 205, as described with respect to FIGS. 1 and 2. In one or more embodiments, the method S100 may include applying film-assisted molding to further enhance the cavity package's hermeticity against leaks and the integrity of the SiC heat spreaders. This results in a package with an exposed oversized heat spreader on top and a cavity package surrounded by SiC as a wall and top lid. This configuration brings the cavity package closer to a near-hermetic level, as SiC does not absorb moisture or water.

In one or more embodiments, the semiconductor package can also undergo sputter shielding to further improve its hermeticity and the integrity of the heat spreader. In one or more embodiments, the method S100 may further include, optionally at step S160, forming a shielding to encapsulate the mold compound. In one or more embodiments, the shielding includes a shielding, such as the shielding 190 or 290, as described with respect to FIGS. 1 and 2. In one or more embodiments, a wireless device may include the semiconductor package produced via the method S100 as disclosed herein. The semiconductor package produced via the method S100 can enhance RF performance, while over molding the semiconductor package can improve robustness.

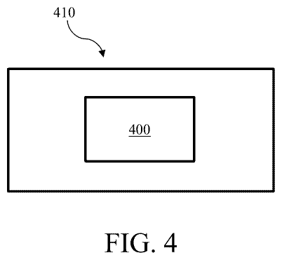

FIG. 4 illustrates an electronic device or a wireless device 410 comprising a semiconductor package 400, according to aspects of the present disclosure. In some implementations, the electronic device or wireless device 410 may include, for example, but not limited to, a computer, a cellular device, a satellite communication device, a wi-fi device, a radar, a global position system device, or other electronic device that implements a wireless communication or radar application. The semiconductor package 400 may implement RF circuitry used in wireless communication or radar applications, as examples, such as one or more RF power amplifiers. In one or more embodiments, the semiconductor package 400 may be coupled to other circuitry for implementing a wireless application, such as a baseband processor or other types of processors. In one or more embodiments, the semiconductor package 400 may be produced in accordance with the method S100 described with respect to FIG. 3, and/or may include a semiconductor package, such as the semiconductor packages 100 and 200, as described with respect to FIGS. 1 and 2.

In one or more embodiments, the semiconductor package 400 includes a substrate; an interposer attached to the substrate, the interposer comprising one or more through vias across the interposer; a flip-chip die attached to the interposer via a plurality of copper posts; and a silicon carbide heat spreader disposed on atop the FC die via a layer of sinter material.

In one or more embodiments of the wireless device 410, the one or more through vias of the interposer comprises copper and are configured to enable thermal conduction through and across the interposer. In one or more embodiments, the interposer has a larger lateral surface area than a lateral surface area of the FC die. In one or more embodiments, the interposer comprises a silicon carbide (SiC) thermal spreader and the one or more through vias comprises one or more through-silicon carbide vias.

In one or more embodiments of the wireless device 410, the SiC heat spreader is a first SiC heat spreader and the layer of sinter material is a first layer of sinter material, the semiconductor package 400 may further include a second SiC heat spreader disposed atop the first SiC heat spreader via a second layer of sinter material. In one or more embodiments, the second SiC heat spreader is larger than the first SiC heat spreader and comprises extensions that are in thermal contact with the substrate via a third layer of sinter material.

In one or more embodiments, the semiconductor package 400 may further include a mold compound surrounding the FC die and the interposer. In one or more embodiments, the semiconductor package 400 may further include a shielding encapsulating the mold compound. In one or more embodiments, the plurality of copper posts are in thermal contact with the one or more through vias.

In one or more embodiments, a wireless device 410 may include a semiconductor package, such as the semiconductor package 400, comprising a substrate, an interposer attached to the substrate, the interposer comprising one or more through vias across the interposer, a flip-chip die attached to the interposer via a plurality of copper posts, and a silicon carbide heat spreader disposed on atop the flip-chip die via a layer of sinter material.

Persons skilled in the art will recognize that the apparatus, systems, and methods described above can be modified in various ways. Accordingly, persons of ordinary skill in the art will appreciate that the embodiments encompassed by the present disclosure are not limited to the particular exemplary embodiments described above. In that regard, although illustrative embodiments have been shown and described, a wide range of modification, change, and substitution is contemplated in the foregoing disclosure. It is understood that such variations may be made to the foregoing without departing from the scope of the present disclosure. Accordingly, it is appropriate that the appended claims be construed broadly and in a manner consistent with the present disclosure.

1. A semiconductor package, comprising:
a substrate;
an interposer attached to the substrate, the interposer comprising one or more through vias across the interposer;
a flip-chip (FC) die attached to the interposer via a plurality of copper posts; and
a silicon carbide (SiC) heat spreader disposed on atop the FC die via a layer of sinter material.

2. The semiconductor package of claim 1, wherein the one or more through vias of the interposer comprises copper and are configured to enable thermal conduction through and across the interposer.

3. The semiconductor package of claim 1, wherein the interposer has a larger lateral surface area than a lateral surface area of the FC die.

4. The semiconductor package of claim 1, wherein the interposer comprises a silicon carbide (SiC) thermal spreader and the one or more through vias comprises one or more through-silicon carbide vias.

5. The semiconductor package of claim 1, wherein the SiC heat spreader is a first SiC heat spreader and the layer of sinter material is a first layer of sinter material, the semiconductor package further comprises:
a second SiC heat spreader disposed atop the first SiC heat spreader via a second layer of sinter material.

6. The semiconductor package of claim 5, wherein the second SiC heat spreader is larger than the first SiC heat spreader and comprises extensions that are in thermal contact with the substrate via a third layer of sinter material.

7. The semiconductor package of claim 1, further comprising:
a mold compound surrounding the FC die and the interposer.

8. The semiconductor package of claim 7, further comprising:
a shielding encapsulating the mold compound.

9. The semiconductor package of claim 1, wherein the plurality of copper posts are in thermal contact with the one or more through vias.

10. A wireless device or module comprising the semiconductor package of claim 1.

11. A method, comprising:
attaching an interposer to a substrate, the interposer comprising one or more through vias across the interposer;
attaching a flip-chip (FC) die to the interposer via a plurality of copper posts; and
disposing a silicon carbide (SiC) heat spreader atop the FC die via a layer of sinter material.

12. The method of claim 11, wherein the one or more through vias of the interposer comprises copper and are configured to enable thermal conduction through and across the interposer.

13. The method of claim 11, wherein the interposer has a larger lateral surface area than a lateral surface area of the FC die.

14. The method of claim 11, wherein the interposer comprises a silicon carbide (SiC) thermal spreader and the one or more through vias comprises one or more through-silicon carbide vias.

15. The method of claim 11, wherein the SiC heat spreader is a first SiC heat spreader and the layer of sinter material is a first layer of sinter material, the method further comprises:
attaching a second SiC heat spreader atop the first SiC heat spreader via a second layer of sinter material.

16. The method of claim 15, wherein the second SiC heat spreader is larger than the first SiC heat spreader and comprises extensions that are in thermal contact with the substrate via a third layer of sinter material.

17. The method of claim 11, further comprising:
forming a mold compound to surround the FC die and the interposer; and
forming a shielding to encapsulate the mold compound.

18. The method of claim 11, wherein the plurality of copper posts are in thermal contact with the one or more through vias.

19. A semiconductor package produced via the method of claim 11.

20. A wireless device comprising:
a semiconductor package comprising a substrate, an interposer attached to the substrate, the interposer comprising one or more through vias across the interposer, a flip-chip die attached to the interposer via a plurality of copper posts, and a silicon carbide heat spreader disposed on atop the flip-chip die via a layer of sinter material.
